(19) United States
(12) Patent Application Publication
(10) Pub. No.: US 2008/0169485 A1
(43) Pub. Date: Jul. 17, 2008

(54) FIELD EFFECT TRANSISTOR DEVICE AND METHOD OF PRODUCING THE SAME

(75) Inventors: Marc Heyns, Linden (BE); Marc Meuris, Keerbergen (BE)

Correspondence Address: KNOBBE MARTENS OLSON & BEAR LLP, 2040 MAIN STREET, FOURTEENTH FLOOR, IRVINE, CA, 92614, US

(73) Assignee: Interuniversitair Microelektronica Centrum (IMEC) vzw, Leuven (BE)

(21) Appl. No.: 11/963,615

(22) Filed: Dec. 21, 2007

(30) Foreign Application Priority Data
Dec. 22, 2006 (EP) EP06127148.2

(51) Int. Cl. H01L 29/78; H01L 21/20

(52) U.S. Cl. 257/194; 438/478; 257/E29.255; 257/E21.09

(57) ABSTRACT

A semiconductor device is disclosed. In one aspect, the device comprises a channel area, the channel area comprising a channel layer in which charge carriers can move when the transistor is turned on, in order to pass a current through the transistor. The device further comprises a source area and a drain area contacting the channel layer for providing current to and from the channel layer. The method further comprises a gate electrode, preferably provided with a gate dielectric between the gate electrode and the channel layer. The channel layer may comprise a III-V material, and the source and drain areas comprise SiGe, being SixGe1-x, with x between 0 and 100%, arranged so that heterojunctions are present between III-V material and SiGe, wherein the heterojunctions are oriented so as to intersect with the gate dielectric or the gate electrode.

### BACKGROUND OF THE INVENTION

1. Field of the Invention

The present invention is related to a method for producing a semiconductor transistor device, e.g. a metal-oxide semiconductor field-effect transistor (MOSFET) or High Electron Mobility Transistor (HEMT), using semiconductor materials such as III-V materials (e.g. GaAs), preferably III-V materials with a high bandgap (>1eV), and Ge, in order to create a device with improved capabilities.

2. Description of the Related Technology

The use of Ge, SiₓGe₁₋ₓ and of III-V materials such as GaAs, is known in the production of semiconductor devices. These materials have superior characteristics in terms of the mobility of charge carriers (electrons or holes), which makes them highly suitable for the production of improved FET devices.

However, a number of problems have been acknowledged, in particular in relation to the use of III-V materials in CMOS technology. Ion implantation of GaAs for example is not an easy operation, due to the difficulty of annealing out the defects, after the ion bombardment of a GaAs area. Another problem is the contacting of III-V materials. On GaAs and other similar materials, it is difficult to obtain low resistive contacts, and complex metallization schemes have to be used.

U.S. Pat. No. 5,036,374 highlights problems involved with the use of III-V materials or Ge in MOSFET devices, mainly in relation to the difficulty of providing a high quality dielectric on the channel layer. A MOSFET is proposed with a channel, source and drain in GaAs, and with a single crystal Si thin film between the channel and the dielectric. One embodiment suggests a GaAs or Ge channel in combination with Si source and drain areas, however with the channel being produced by Metal-Organic Chemical Vapor Deposition (MOCVD) or Molecular Layer Epitaxy (MLE) on top of a Si substrate comprising the source and drain areas.

JP62266873 is related to a HEMT device wherein Ge layers are used to block incident light on an AlGaAs electron supplying layer. Ge layers are supplied at the upper and lower parts of the AlGaAs layer.

In the above-cited documents, heterojunctions are oriented horizontally, thereby limiting the extent to which the gate is able to control during operation of the device the heterojunction energy barrier properties, due to the spacing between the gate dielectric and the heterojunction.

### SUMMARY OF CERTAIN INVENTIVE ASPECTS

Certain inventive aspects relate to a semiconductor transistor device, such as a MOSFET or HEMT which provides a solution for the problems identified above. Particularly, some inventive aspects relate to devices and methods such as described in the appended claims. Preferred embodiments of the device and method are disclosed in combinations of the independent claims with one or more of the dependent claims.

One inventive aspect relate to a semiconductor transistor device, provided with a source and drain area produced in or on a semiconductor substrate, more particularly in or on a so-called ‘active area’ of a substrate, which is delimited by field areas (field oxides/dielectric areas).

One inventive aspect relate to a semiconductor transistor device comprising a channel area, the channel area comprising:

a channel layer in which charge carriers can move when the transistor is turned on, in order to pass a current through the transistor,

a source area and a drain area, contacting the channel layer for providing current to and from the channel layer,

wherein the channel layer comprises a III-V material, and the source and drain areas comprise SiₓGe₁₋ₓ, with x between 0 and 100%, arranged so that heterojunctions are present between III-V material and SiₓGe₁₋ₓ, the heterojunctions being arranged so that the current passes through the heterojunctions. In one application, the channel layer consists of a III-V material.

According to a first embodiment, the areas are provided in a substrate and the substrate comprises a top layer of the III-V material, and two openings are present in the top layer, and the openings have been filled with SiGe, to form the source and drain areas.

According to a second embodiment, the areas are provided in a substrate and the substrate comprises a top layer of Siₓ Ge_{1 -x},and an opening is present in the top layer, and the opening has been filled with III-V material, to form the channel area.

The III-V material may be chosen from the group of GaAs, AlP, GaP, AlAs, InGaNAs, InGaAs, InP and AlSb.

The source and/or drain area may be provided with a contact portion comprising a metal germanide and/or silicide. In one application, the contact portion consists of a metal germanide and/or silicide.

The device may be a MOSFET or a HEMT.

One inventive aspect relate to a method for producing a device, the method comprising:

providing a substrate having a top layer comprising a III-V material,

by a photolithographic technique, etching back two cavities in the III-V layer, to form a channel area in between the cavities,

filling up the cavities with SiGe, to form source and drain areas in contact with the channel area.

In one application, the top layer may consist of a III-V material.

According to a second embodiment, a method for producing a device is provided, the method comprising:

providing a substrate having a top layer comprising SiGe,

by a photolithographic technique, etching back a cavity in the SiGe layer, for forming a channel area,

filling up the cavity with III-V material, to form the channel area.

In one application, the top layer may consist of SiGe.

In the above, a ‘III-V substrate’ and a ‘SiGe’ substrate’ can be substrates made of such materials, or substrates comprising a top layer of such materials.

According to one embodiment, x is smaller than 100%. According to other embodiments, x is—respectively—smaller than 90%, 80% and 70%.

The device equally comprises a gate electrode, preferably provided with a gate dielectric between the gate electrode and the channel layer. In one embodiment, the heterojunctions are oriented so as to intersect, i.e. be in physical contact with the gate dielectric or with the gate electrode (when no gate dielectric is present). The heterojunctions are not parallel to the plane of the substrate in which the areas are provided, the plane being defined by the top surface of the substrate, i.e. the heterojunctions are not horizontal when the substrate is oriented horizontally.

There are two embodiments for obtaining the above features:

Either the substrate comprises a top layer of III-V material, and two openings are present in the top layer, and the openings have been filled with SiGe, to form the source and drain areas. In other words, the upper layer of the III-V substrate comprises two SiGe regions, which form the source and drain areas. The SiGe regions have a given depth (i.e. are embedded in the substrate), and are thus laterally adjacent to III-V material, OR:

The substrate comprises a top layer of SiGe, and an opening is present in the top layer, and the opening has been filled with III-V material, to form the channel area. In other words, the upper layer of the SiGe substrate comprises a region comprising III-V material, the region forming the channel area. The III-V region has a given depth (i.e. is embedded in the substrate) and is thus laterally adjacent to SiGe. In one application, the region in the upper layer of the SiGe substrate consists of III-V material.

### BRIEF DESCRIPTION OF THE DRAWINGS

FIG. 1 represents a device according to a first embodiment of the invention.

FIG. 2 represents a device according to a second embodiment of the invention.

FIG. 3 illustrates a device of one embodiment wherein source and drain areas are subjected to a germanidation.

FIG. 4 represents a graph showing III-V materials which may be included in one embodiment.

FIG. 5 represents a specific example of a device according to the first embodiment.

FIG. 6 represents an example of a HEMT device according to one embodiment.

### DETAILED DESCRIPTION OF CERTAIN INVENTIVE EMBODIMENTS

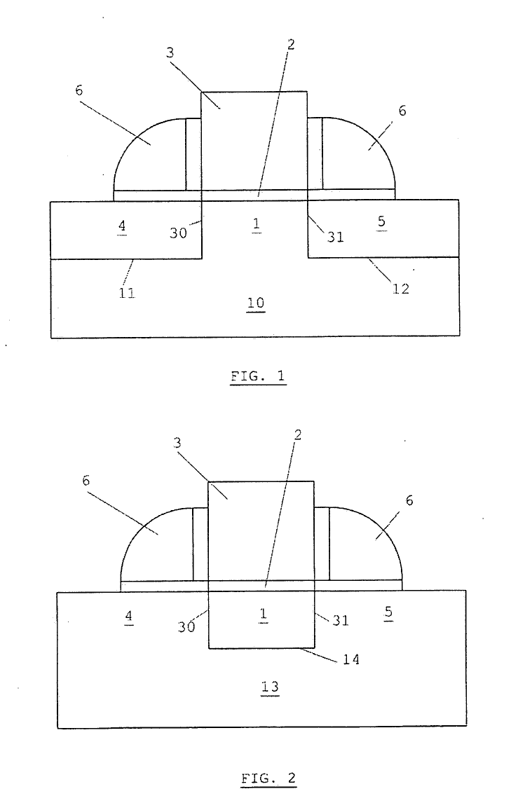

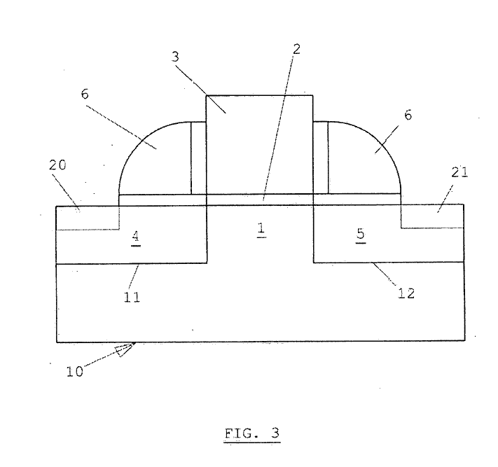

Certain embodiments relate to a semiconductor transistor device, for example a MOSFET, such as shown in FIGS. 1 and 2. The figures show only the active area on which one device is built. It is to be understood that field areas surround the device shown in each drawing. A MOSFET according to one embodiment comprises the classic components, namely a first semiconductor area called the channel 1, located underneath the gate dielectric 2 and gate electrode 3. The channel lies in between two semiconductor areas 4 and 5, called source and drain areas respectively. Spacers 6 are normally present on either side of the gate 3. In the case of a MOSFET, as shown in the drawings, the actual channel is the interface between the top layer (called ‘channel layer’ in the context of this patent application) in the channel area 1 and the dielectric 2. In one embodiment, at least the channel layer of the channel area comprises a III-V material, for example GaAs, while the source and drain areas comprise SiGe, so that a heterojunction (30,31) is formed in each of the border areas between III-V material and SiGe, the heterojunction being arranged so that the current flowing in the channel passes through the heterojunction. In one embodiment, the channel layer consists of a III-V material.

In a HEMT device, the structure is similar to the one shown in FIGS. 1 and 2, but the channel area 1 is built from several layers, designed to obtain a 2-dimensional electron gas in a conducting layer sandwiched between two active layers. The dielectric layer 2 is not necessarily present in a HEMT device. In a HEMT according to one embodiment, at least one of the active layers (the channel layer) comprises a III-V material, while the source and drain areas comprise SiGe, so that again, a heterojunction is formed in each of the border areas between III-V material and SiGe, the heterojunction being arranged so that the current flowing through the channel passes through the heterojunction. In one embodiment, the semiconductor device is characterized by the presence of a heterojunction between SiGe and III-V material, the heterojunction being arranged so that the current flowing through the channel passes through the heterojunction. In one embodiment, the channel layer consists of a III-V material.

In one embodiment, the heterojunctions referred to above are not parallel to the plane of the substrate (i.e. heterojunctions are not horizontal in the appended drawings). According to the embodiments shown in the drawings, the heterojunctions are vertically oriented. The heterojunctions are oriented so as to intersect, i.e. be in physical contact with the gate dielectric 2 or with the gate electrode 3 (when no gate dielectric is present as in a HEMT e.g.). This feature ensures a close proximity of the heterojunctions to the gate and thereby an optimal control by the gate over the barrier properties of the heterojunctions. The gate thus extends over both sides of the heterojunction and controls the tunneling through the energy barrier of the heterojunction from both sides.

The term ‘SiGe’ (silicon-germanium) is to be understood in the context of this application as SiₓGe₁₋ₓ, with x between 0 and 100%, so it is a range of materials with differing concentrations of Si and Ge, the included limits being pure Si and pure Ge. This is the way ‘SiGe’ is generally interpreted by a person skilled in the art of semiconductor technology. Where appropriate, the full expression ‘SiₓGe₁₋ₓ’ is used, otherwise simply ‘SiGe’. Preferred embodiments exclude the use of pure Si in various ranges (respectively, x<100%, <90%, <80% and <70%).

According to a first embodiment, shown in FIG. 1, the device comprises a substrate 10 of III-V material, wherein openings, i.e. cavities 11, 12 have been produced, e.g., by etching, and wherein the openings have been filled with SiGe, to form the source and drain areas 4,5. In other words, the upper layer of the III-V substrate comprises two SiGe regions, which form the source and drain areas 4 and 5. The SiGe regions have a given depth, and are thus laterally adjacent to the III-V material of the channel area.

According to a second embodiment, shown in FIG. 2, the device comprises a substrate 13 of SiGe, wherein an opening, i.e. a cavity 14 has been produced, e.g. by etching, and wherein the opening has been filled with a III-V material, e.g. GaAs, to form the channel area 1. In other words, the upper layer of the SiGe substrate comprises a region comprising III-V material, the region forming the channel area 1. The III-V region has a given depth and is thus laterally adjacent to the SiGe of the source and drain areas. In one application, the region in the upper layer of the SiGe substrate consists of III-V material.

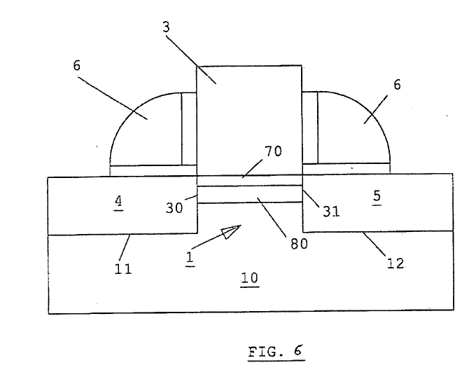

In both cases, the final result is a MOSFET (or a HEMT, FIG. 6), comprising a III-V channel 1 and SiGe source and drain areas 4 and 5. In both embodiments, the difficulty of doping the source and drain areas is no longer present, because SiGe can be easily doped by ion-implantation or in-situ doping techniques. Furthermore, SiGe can be easily contacted through various metallization schemes.

Germanidation and/or silicidation can be used (for example by forming Nickel Germanide—NiGe) on the SiGe regions, to form a region in the source and drain areas, the region comprising a metal germanide and/or silicide, the region facilitating the contacting of the source and drain. In one application, the region consists of a metal germanide and/or silicide. According to an embodiment, after producing source and drain areas in SiGe, as in embodiments 1 and 2, preferably in pure Ge, a layer of a metal, e.g. Ni, is applied on the substrate, so that a region (20, 21) of NiGe is formed near the surface of the substrate, see FIG. 3. The formation of NiGe preferably occurs by applying a continuous layer of Ni on the totality of the substrate, and allowing NiGe to form on the Ge-regions. After that, the unreacted Ni on the remaining areas is removed by an etching process. This type of self-aligned production of NiGe-areas is known in the art. Other types of metal may be used, in combination with a source/drain area with various concentrations of Si and Ge in the SiₓGe₁₋ₓ areas, to form a metallic region by an alloy of a metal such as Pt, Pt, Co, Ni with the semiconductor material, SiₓGe₁₋ₓ. When x is between 0 and 100 excluding the boundary values, a mixed germanide/silicide compound will be formed with the applied metal.

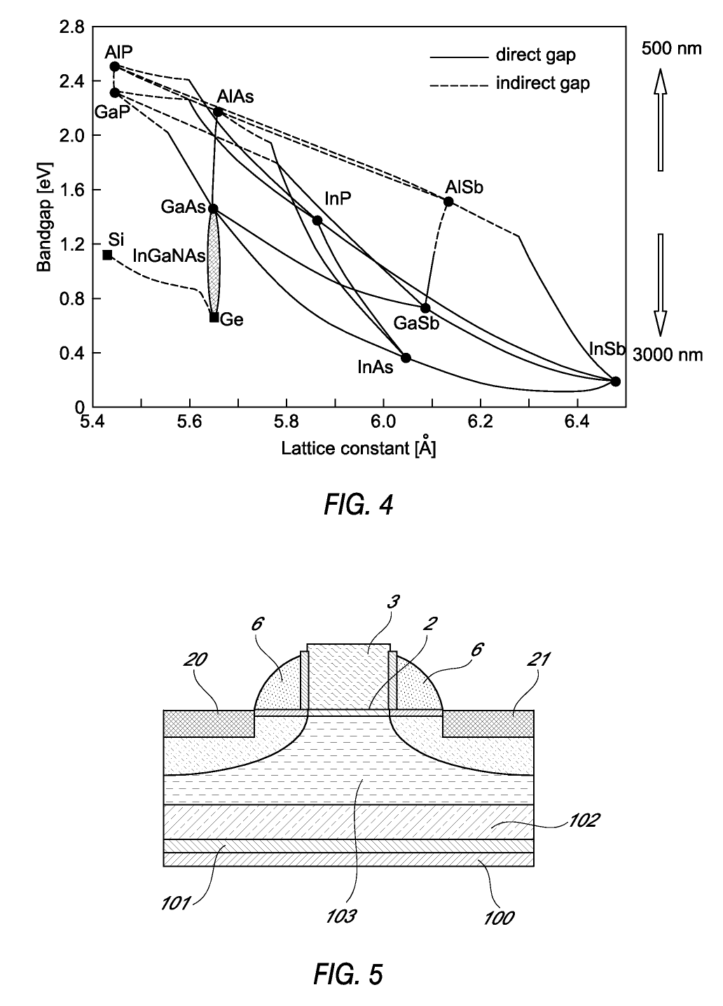

In one embodiment, the III-V material used for the channel area 1 is chosen from the list of: GaAs, AlP, GaP, AlAs, InGaNAs, InGaAs, InP and AlSb. These materials have a bandgap above 1 eV (FIG. 4). The III-V material can also be a mixture of these elements. The channel material may also be a III-V material with a low bandgap (i.e. <1 eV).

The material of the source and drain 4 and 5 is SiGe, which is actually SiₓGe₁₋ₓ, with x between 0 and 100%, as explained above.

The heterojunctions formed by the SiGe and III/V material will in the case of Germanium and GaAs most likely have a band alignment along the conduction band edge of these materials, making these junctions ideally suited for NMOS applications. Other III/V materials may have similar properties or may alternatively be used for pMOS when band alignment occurs at the valence band edge of these materials.

In one embodiment, the III-V material and the source/drain material have substantially the same lattice constant. Certain combinations are, for example, GaAs/Ge or AlAs/Ge, as can be derived from the graph in FIG. 4. The substrates 10 and 13 can be bulk crystalline GaAs or SiGe substrates, or they can in turn be layers of GaAs or SiGe, applied by a deposition or layer transfer technique on another substrate, for example a silicon wafer. Such substrates are known: germanium-on-insulator (GOI), whereby a crystalline germanium layer upon a dielectric layer is present for growing layers of III/V material or silicon-on-insulator whereby a crystalline silicon layer upon a dielectric is present for growing silicon/germanium and germanium layers upon which layers of III/V material can be formed.

FIG. 5 shows a specific embodiment of a MOSFET according to the first embodiment, comprising on a Si-wafer 100:

a graded Si/Ge layer 101, having a low concentration of Ge near the interface with Si, and a growing Ge-concentration while progressing to the opposite side, up to virtually 100% Ge at the top,

a Ge layer 102, grown by selective epitaxy,

a III-V layer 103, e.g. GaAs or GaₓIn₁₋ₓAs, grown by selective MOCVD on Ge.

The layer 103 is then equivalent to the substrate 10 of FIG. 1. On this layer 103, the Ge-source and drain 4 and 5 are formed, e.g. by etching of the GaAs and epitaxial growth of Ge on GaAs. The device of FIG. 5 may also be built on a GeOI substrate (Germanium on Insulator) whereby layer 102 is then formed upon a dielectric layer.

The method of producing a device according to the first embodiment of the invention, comprises:

providing a substrate having a top layer comprising of III-V material. This can be a III-V wafer 10, or a Si wafer 100 with a III-V layer 103 deposited on it, possibly with other layers (101,102) between the Si and the III-V, as shown for example in FIG. 5,

by photolithographic techniques, etching back two cavities 11 and 12 in the III-V layer, to form a channel area 1 in between the cavities,

filling up the cavities with SiGe, preferably by a selective deposition technique, e.g. by epitaxial growth, to form source and drain areas 4 and 5 in contact with the channel area 1. Other techniques can be applied to selectively form SiGe in the cavities, e.g. by uniform growth and subsequent removal of the SiGe outside the cavities using photolithographic patterning and etching processes known in the art.

In one embodiment, the top layer consists of III-V material.

The method of producing a device according to the second embodiment of the invention, comprises:

providing a substrate having a top layer comprising SiGe. This can be a SiGe wafer 13, or a Si wafer with a SiGe layer deposited on it, possibly with other layers between the Si and the SiGe,

by photolithographic techniques, etching back a cavity 14 in the III-V layer, for forming a channel area 1,

filling up the cavity with III-V material, preferably by a selective deposition technique, e.g. by epitaxial growth, to form the channel area 1.

In one embodiment, the top layer consists of SiGe.

The method according to both embodiments, can then be followed by processes of doping the SiGe source and drain regions, and producing source, drain and gate contacts, by methods known in the art.

As stated above, the invention is not limited to MOSFET devices. Also in other types of transistors, source and drain areas can be produced in SiGe, to form non-horizontal heterojunctions with e.g. GaAs. This can be the case for example in HEMT transistors (High Electron Mobility Transistor). As mentioned above, in a HEMT transistor, the structure of the III-V layer will be different from the case of a MOSFET, and will comprise multiple layers of III-V material. An example of such a HEMT structure is shown in FIG. 6. Active layers 70 and 80 are present underneath the gate electrode 3. At least the channel layer 80 is a III-V layer, e.g. a GaN layer. Layer 70 can also be III-V, e.g. AlGaN, as is known in the art. The channel can be formed at the interface between layers 70 and 80. If a third layer is present adjacent layer 80 opposite layer 70 then a two dimensional carrier gas is created in the channel layer 80 thereby forming a conductive path between source 4 and drain 5.

The foregoing description details certain embodiments of the invention. It will be appreciated, however, that no matter how detailed the foregoing appears in text, the invention may be practiced in many ways. It should be noted that the use of particular terminology when describing certain features or aspects of the invention should not be taken to imply that the terminology is being re-defined herein to be restricted to including any specific characteristics of the features or aspects of the invention with which that terminology is associated.

While the above detailed description has shown, described, and pointed out novel features of the invention as applied to various embodiments, it will be understood that various omissions, substitutions, and changes in the form and details of the device or process illustrated may be made by those skilled in the technology without departing from the spirit of the invention. The scope of the invention is indicated by the appended claims rather than by the foregoing description. All changes which come within the meaning and range of equivalency of the claims are to be embraced within their scope.

What is claimed is:

1. A semiconductor transistor device comprising:
a channel area comprising a channel layer in which charge carriers move when the transistor is turned on, in order to pass a current through the transistor;
a source area and a drain area, contacting the channel layer for providing current to and from the channel layer; and
a gate electrode;
wherein the channel layer comprises a III-V material, and the source and drain areas comprise SiGe, being SiₓGe₁₋ₓ, with x between 0 and 100%, arranged so that heterojunctions are present between III-V material and SiGe, the heterojunctions being arranged so that current passes through the heterojunctions, wherein the heterojunctions are oriented so as to intersect with the gate electrode.

2. The device according to claim 1, further comprising a substrate, the substrate comprising a top layer of the III-V material, and wherein two openings are present in the top layer, and wherein the openings have been filled with SiGe, to form the source and drain areas.

3. The device according to claim 1, further comprising a substrate, wherein the substrate comprises a top layer of SiGe, and wherein an opening is present in the top layer, and wherein the opening has been filled with III-V material, to form the channel area.

4. The device according to claim 1, wherein the III-V material is chosen from the following group: GaAs, AlP, GaP, AlAs, InGaNAs, InGaAs, InP and AlSb.

5. The device according to claim 1, wherein the source and/or drain area are provided with a contact portion comprising a metal germanide and/or silicide.

6. The device of claim 5, wherein the contact portion consists essentially of a metal germanide and/or silicide.

7. The device according to claim 1, wherein the device is a MOSFET.

8. The device according to claim 1, wherein the device is a HEMT.

9. The device according to claim 1, further comprising a gate dielectric between the gate electrode and the channel layer, wherein the heterojunctions are oriented so as to intersect with the gate dielectric.

10. The device according to claim 1, wherein the channel layer consists essentially of a III-V material.

11. The device according to claim 1, wherein x is less than 100%.

12. The device according to claim 1, wherein x is less than 90%.

13. The device according to claim 1, wherein x is less than 80%.

14. The device according to claim 1, wherein x is less than 70%.

15. A method of producing a semiconductor device, the method comprising:
providing a substrate having a top layer comprising a III-V material;
by a photolithographic technique, etching back two cavities in the III-V layer, to form a channel area in between the cavities; and
filling the cavities with SiGe, to form source and drain areas in contact with the channel area.

16. A method of producing a semiconductor device, the method comprising:
providing a substrate having a top layer comprising SiGe;
by a photolithographic technique, etching back a cavity in the SiGe layer for forming a channel area; and
filling the cavity with III-V material to form the channel area.

17. A semiconductor device comprising:
a channel layer; and
heterojunctions are formed between III-V material and SiGe, the heterojunctions are arranged so that current flowing through the channel layer passes through the heterojunctions.

18. A semiconductor device comprising:
a channel layer; and
heterojunctions oriented toward the channel layer, the heterojunctions being arranged so that current flowing through the channel passes through the heterojunctions.

19. The semiconductor device according to claim 18, wherein the heterojunctions are approximately perpendicular to the channel layer.
